(19) United States
(12) Patent Application Publication
(10) Pub. No.: US 2006/0145177 A1
(43) Pub. Date: Jul. 6, 2006

(54) Light emitting device and process for fabricating the same

(76) Inventors: Kazunori Hagimoto, Gunma (JP); Masato Yamada, Gunma (JP)

Correspondence Address: ARENT FOX PLLC, 1050 CONNECTICUT AVENUE, N.W., SUITE 400, WASHINGTON, DC, 20036, US

(21) Appl. No.: 10/546,201

(22) PCT Filed: Dec. 19, 2003
(86) PCT No.: PCT/JP03/16322

§ 371 Date: Aug. 18, 2005

(30) Foreign Application Priority Data
Feb. 28, 2003 (JP) 2003-53690

(51) Int. Cl. H01L 33/00

(52) U.S. Cl. 257/99

(57) ABSTRACT

A light emitting device 100 of the invention is the one using a first main surface of a compound semiconductor layer portion, having a light emitting layer section 24 therein, as a light extraction surface, and having, on the second main surface side of the compound semiconductor layer, a device-substrate 7 bonded thereto while placing, in between, a main metal layer 10 having a reflective surface reflecting light from the light emitting layer section 24 towards the light extraction surface side, and is characterized in that the device-substrate 7 is composed of a Si substrate having a conductivity type of p type, and that the device-substrate 7 has, as being formed on the main surface thereof on the main metal layer 10 side, a contact layer 31 having Al as a major component. With respect to light emitting devices configured as having a structure in which a light emitting layer section and a device-substrate are bonded while placing a metal layer in between, the invention is successful in providing a light emitting device having a desirable electro-conductivity, and a method of fabricating the same.

### FIELD OF THE INVENTION

This invention relates to a light emitting device and a method of fabricating the same.

### BACKGROUND ART

After years of advancement made in materials and device structures adopted to light emitting devices such as light emitting diode and semiconductor laser, photo-electric conversion efficiency within the device have been getting more and more closer to the theoretical limit. Light extraction efficiency from the device will, therefore, hold the key for efforts of obtaining devices with higher luminance. For example, a light emitting device having a light emitting layer section composed of an AlGaInP alloy formed therein can be realized as a high luminance device, by adopting a double heterostructure in which a thin AlGaInP (or GaInP) active layer is sandwiched by an n-type AlGaInP cladding layer and a p-type AlGaInP cladding layer larger in the band gap energy. This sort of AlGaInP double heterostructure can be formed by epitaxially growing the individual layers composed of AlGaInP alloy on a GaAs single crystal substrate, based on the fact that AlGaInP can be lattice-matched with GaAs. For the purpose of using the structure as a light emitting device, it is general and often to use the GaAs single crystal substrate directly as a device-substrate. This, however, raises difficulty in obtaining a sufficient level of light extraction efficiency due to absorption of emitted light by the GaAs substrate, because AlGaInP alloy composing the light emitting layer section has a larger band gap than GaAs has. Aiming at solving this problem, there has been proposed a method of inserting a reflective layer composed of a semiconductor multi-layered film between the substrate and the light emitting layer section (e.g., Japanese Laid-Open Patent Publication “Tokkaihei” No. 7-66455), but a distinctive improvement in the light extraction efficiency cannot be expected on the principle basis, because the method, making use of difference in refractive indices of the stacked semiconductor layers, can reflect only light incident at a limited range of angle.

Various patent publications including Japanese Laid-Open Patent Publication No. 2001-339100 disclose techniques by which the GaAs substrate for the growth is separated off, and another device-substrate for reinforcement, composed of a semiconductor, is bonded to the separation surface while placing an Au layer for reflection in between. The Au layer is advantageous in having a large reflectivity, and in having only a small incident angle dependence of the reflectivity.

In view of obtaining a necessary level of emission intensity of the light emitting device, it is preferable to supply as large as possible current to the light emitting layer section. This consequently demands electro-conductivity of the device-substrate durable thereto. The device-substrate composed of a semiconductor, however, does not always show a sufficient level of electro-conductivity allowing large current supply to the light emitting layer section.

It is therefore a subject of the invention with respect to light emitting devices configured as having a structure in which a light emitting layer section and a device-substrate are bonded while placing a metal layer in between, to provide a light emitting device having a desirable electro-conductivity, and a method of fabricating the same.

### SUMMARY OF THE INVENTION

Aiming at solving the aforementioned problems, a light emitting device of the invention is such as using a first main surface of a compound semiconductor layer portion, having a light emitting layer section therein, as a light extraction surface, and having, on the second main surface side of the compound semiconductor layer, a device-substrate bonded thereto while placing, in between, a main metal layer having a reflective surface reflecting light from the light emitting layer section towards the light extraction surface side, and is characterized in that the device-substrate is composed of a Si substrate having a conductivity type of p type, and that the device-substrate has, as being formed directly on the main surface thereof on the main metal layer side, a contact layer having Al as a major component.

It is to be noted herein that “major component” and “mainly composed of” in this patent specification mean a component having a largest content by mass. In this patent specification, “main metal layer” is a metal layer disposed between the compound semiconductor layer and the contact layer, forming the reflection surface, and at the same time taking part in bonding the compound semiconductor layer and the contact layer. It is therefore defined that a diffusion blocking layer and a bonding metal layer on the light emitting layer section side, described later, are not included in the scope of the main metal layer.

In the configuration of the light emitting device of the invention, the device-substrate is composed of silicon substrate having a conductivity type of p type (also referred to as p-type Si or p-Si, hereinafter), and directly on the main surface thereof on the main metal layer side, a contact layer having Al (aluminum) as a major component is formed. Because Al and p-type Si can ensure desirable Ohmic contact, it is made possible to effectively suppress excessive rise in the series resistance, and consequently in the forward voltage of the light emitting device, in particular within a range of resistivity of the p-type Si from 1/1000 Ω·cm to 10 Ω·cm, both ends inclusive. In this case, effect of lowering the contact resistance can be enhanced by proceeding annealing for alloying of Al and p-type Si, typically within a range from 300 ° C. to 650 ° C., both ends inclusive.

In the light emitting device, the light emitting layer section may be configured so that, as being disposed therein, a p-type compound semiconductor layer on the light extraction surface side thereof, and an n-type compound semiconductor layer on the main metal layer side thereof, and so that the n-type compound semiconductor layer is bonded to the p-type Si substrate while placing the main metal layer in between. In a conventional light emitting device mainly composed of a growth substrate having a light emitting layer grown thereon, there was a limitation on the positional relation of conductivity types of the light emitting layer, such that a layer, out of those composing the light emitting layer, disposed on the substrate side must be configured by a conductivity type same with the conductivity type owned by the substrate (e.g., p-type for a p-type substrate), and a layer disposed on the opposite side (light extraction surface side) must be configured by a conductivity type different from the conductivity type owned by the substrate (e.g., n-type for a p-type substrate). In contrast, in the light emitting device of the invention having the compound semiconductor layer and the device-substrate bonded with each other while placing the main metal layer in between, even combination of different conductivity types, such as p-type Si substrate and n-type compound semiconductor layer allows current supply without problems, by providing the main metal layer therebetween, so that the configuration of the light emitting device of the invention is by no means limited in the positional relation of the conductivity types of the light emitting layer as described in the above. It is therefore made possible, even if the device-substrate is configured by the p-type Si substrate, to dispose the n-type compound semiconductor layer on the p-type Si substrate side (main metal layer side), and the p-type compound semiconductor layer on the light extraction surface side.

The light emitting layer section may be configured by a double heterostructure which comprises a p-type cladding layer as the p-type compound semiconductor layer, an n-type cladding layer as the n-type compound semiconductor layer, and an active layer formed between the p-type cladding layer and the n-type cladding layer. Adoption of this structure is successful in realizing a high luminance device, because holes and electrons injected from both cladding layers can recombine in an efficient manner as being confined in a narrow space of the active layer. It is preferable herein that the n-type cladding layer and the main metal layer are formed in a direct contact with each other, in order to improve the light extraction efficiency through reflection. It is, however, also allowable to insert a heavily-doped thin film between the n-type cladding layer and the main metal layer, in order to lower the operating voltage.

Next, the light emitting device of the invention may be configured so as to further comprise, as being inserted between the contact layer and the main metal layer, a diffusion blocking layer composed of a electro-conductive material, capable of blocking diffusion of an Al component contained in the contact layer. In the light emitting device of the invention, the Al component, which is a major component of the contact layer, may diffuse into the main metal layer, and may denature the main metal layer through reactions (e.g., metallurgical reactions such as generation of eutectic, intermetallic compound, etc.) in the fabrication process, typically when the device-substrate and the compound semiconductor layer are bonded while placing the main metal layer in between, or when the main metal layer or a part thereof is formed on the contact layer. If the above-described configuration is adopted, the Al component, which tends to diffuse from the contact layer to the main metal layer, can be blocked by the diffusion blocking layer, and thereby denaturation of the main meta layer due to reaction with the Al component can effectively be suppressed. As a consequence, this is successful in effectively suppressing nonconformities such as lowering in the reflectivity of the reflective surface formed by the main metal layer, and lowering in adhesion strength between the main metal layer and the compound semiconductor layer, and in making degradation of product yield of the light emitting device ascribable to the nonconformities less likely to occur.

For the case where a portion of the main metal layer including at least the boundary with the diffusion blocking layer is composed of an Au-base layer having Au as a major component, the diffusion blocking layer may specifically be composed of a diffusion blocking metal layer having either one of Ti and Ni as a major component. The metal having Ti or Ni as a major component is particularly excellent in diffusion blocking effect over the Al component towards the Au-base layer, and is preferably applied to the invention. Thickness of the diffusion blocking metal layer is preferably adjusted to 1 nm to 10 μm, both ends inclusive. A thickness of less than 1 nm results in only an insufficient diffusion blocking effect, whereas a thickness exceeding 10 μm saturates the effect and results in waste of the production cost. The diffusion blocking layer can specifically employ industrial pure Ti or pure Ni, wherein it is also allowable to include side components up to a range so far as the effect of blocking the diffusion of the Al component into the Au-base layer is not impaired. For example, addition of an appropriate amount of Pd is effective in increasing corrosion resistance of a metal mainly composed of Ti or Ni. It is also allowable to use an alloy of Ti and Ni.

Next, in the light emitting device of the invention, the reflective surface can be formed by the Au-base layer. The Au-base layer is chemically stable and less likely to be degraded in the reflectivity due to oxidation and so forth, and is suitable for a material for forming the reflective surface. Insertion of the diffusion blocking layer between the contact layer and the Au-base layer also makes it possible to form the reflective layer with a desirable reflectivity by the Au-base layer without any problem, even if a metallurgical reaction between the contact layer and the Au-base layer is anticipated as described in the above.

For the case where the reflective layer is formed by the Au-base layer, it is allowable to arrange the bonding metal layer on the light emitting layer section side, mainly composed of Au, between the Au-base layer and the compound semiconductor layer, in a distributed manner on the main surface of the Au-base layer. The Au-base layer composes a part of current supply route towards the light emitting layer section. Direct boning of the Au-base layer to the light emitting layer section composed of a compound semiconductor may, however, result in increase in the contact resistance, and degradation of the light emission efficiency due to increase in the series resistance. Bonding of the Au-base layer to the light emitting layer section while inserting the Au-base bonding metal layer is successful in reducing the contact resistance. It is to be noted that the Au-base bonding metal layer necessarily contains a relatively large amount of alloying component required for ensuring the contact, and is slightly poor in the reflectivity. Whereas, the distributed formation of the bonding metal layer on the light emitting layer section side on the main surface of the Au-base layer makes it possible to ensure a high reflectivity of the Au-base layer in the non-formation region of the bonding metal layer on the light emitting layer section side.

For the case where the compound semiconductor layer in contact with the bonding metal layer on the light emitting layer section side is composed of an n-type III-V compound semiconductor (e.g., the above described (AlₓGa₁₋ₓ)_{y}In_{1-y}P (where 0≦x≦1 and 0≦y≦1), adoption of an AuGeNi bonding metal layer can extremely raise the effect of reducing the contact resistance. In this case, it is allowable to form the AuGeNi layer on the main surface of the compound semiconductor layer on the bonding side thereof, and to form the Au-base layer so as to cover the AuGeNi bonding metal layer. In this case, annealing for alloying the AuGeNi bonding metal layer and the compound semiconductor layer, carried out within a range from 350° C. to 500° C., is successful in enhancing the effect of reducing the contact resistance.

In view of thoroughly enhancing the light extraction effect, it is preferable to adjust ratio of formation area of the bonding metal layer on the light emitting layer section side to the Au-base layer (which is a value obtained by dividing formation area of the bonding metal layer on the light emitting layer section side by the total area of the Au-base layer) to 1% to 25%. A ratio of formation area of less than 1% results in only an insufficient effect of reducing the contact resistance, whereas exceeding 25% degrades the reflection intensity. The Au-base layer can further be raised in the reflectivity in the non-formation region of the bonding metal layer on the light emitting layer section side, by adjusting the Au content thereof larger than that of the bonding metal layer on the light emitting layer section side.

On the other hand, in the light emitting device having the Au-base layer, the reflective surface may be formed by an Ag-base layer mainly composed of Ag, inserted between the Au-base layer and the compound semiconductor layer. The Ag-base layer is less expensive as compared with the Au-base layer, and even shows a desirable reflectivity almost over the entire wavelength region of the visible light (350 nm to 700 nm), showing only a small wavelength dependence of the reflectivity. This consequently realizes a large light extraction efficiency irrespective of emission wavelength of the device. This is less causative of lowering in the reflectivity due to formation of an oxide film or the like, as compared with metals such as Al.

FIG. 6 shows reflectivity on surfaces of various metals after mirror polishing, wherein plotted dots “▪” represent reflectivity of Ag, plotted dots “Δ” represent reflectivity of Au, and plotted dots “♦” represent reflectivity of Al. Plotted dots “×” are for AgPdCu alloy. Ag shows an especially desirable reflectivity to the visible light within a range from 350 nm to 700 nm (or in the infrared region on the longer wavelength side), in particular within a range from 380 nm to 700 nm.

On the other hand, Au is a colored metal, and, as is obvious from reflectivity shown in FIG. 6, has a strong absorption in the visible light region of 650 nm or shorter wavelength (in particular 650 nm or below: grows still larger at 600 nm or below), so that lowering in the reflectivity becomes distinct when the light emitting layer section has a peak emission wavelength at 670 nm or below. This consequently makes the emission intensity more likely to decrease, and tends to alter the emission color tone because the spectrum of extracted light is altered from the original emission spectrum due to absorption. Whereas, Ag shows a desirable reflectivity also in the visible light region of 670 nm or below. In other words, the reflective surface composed of the Ag-base layer can realize a far more larger light extraction efficiency than the Au-base metal layer can, when the light emitting layer section shows a peak emission wavelength at 670 nm or below (in particular 650 nm or below, and still in particular 600 nm or below).

As is known from FIG. 6, Al does not show a large drop in the reflectivity, but the reflectivity in the visible light region remains slightly low (e.g., 85% to 92%) due to decrease in the reflectivity through formation of an oxide film. On the other hand, Ag-base metal is less likely to form the oxide film, and can therefore ensure a higher reflectivity in the visible light region than Al can. More particularly, it is known that Ag shows more desirable reflectivity than Al shows at a wavelength of 400 nm or above (in particular 450 nm or above).

It is to be noted that the reflectivity of Al shown in FIG. 6 was obtained by measurement of the Al surface after mirror-finished by mechanical polishing and chemical polishing under suppressive conditions over the formation of oxide film, so that actual reflectivity may be lower than the data shown in FIG. 6 due to formation of a thick oxide film. Ag is inferior to Al in the reflectivity in a short wavelength region from 350 nm to 400 nm, but is far less likely to produce the oxide film than Al is. Practical use of the Ag-base film as the reflective metal layer on the light emitting device can, therefore, attain a reflectivity superior to that of Al also in this wavelength region. Also in this wavelength region, reflectivity of Ag is higher than that of Au.

It can be concluded that the Ag-base layer shows a distinctive effect of improving the light extraction efficiency superior to Al and Au, when the light emitting layer section has a peak emission intensity in a wavelength region from 350 nm to 670 nm (more preferably from 400 nm to 670 nm, and still more preferably from 450 nm to 600 nm). The light emitting layer section having such peak emission wavelength can be configured as having a double heterostructure in which a first conductivity type cladding layer, an active layer, and a second conductivity type cladding layer, typically composed of (AlₓGa₁₋ₓ)_{y}In_{1-y} P (where 0≦x≦1, 0≦y≦1) or InₓGa_{y}Al_{1-x-y}N (where 0≦x≦1, 0≦y≦1, x+y≦1) are stacked in this order.

For the case where the Ag-base layer is used for forming the reflective surface, it is allowable to arrange an Ag-base bonding metal layer mainly composed of Ag in a form distributed over the main surface of the Ag-base layer, as the bonding metal layer on the light emitting layer section side, between the Ag-base layer and the compound semiconductor layer. For the case where the compound semiconductor layer, in contact with the Ag-base bonding metal layer, is composed of an n-type III-V compound semiconductor (e.g., the above-described (AlₓGa₁₋ₓ)_{y}In_{1-y} P (where 0≦x≦1, 0≦y≦1)), adoption of an AgGeNi bonding metal layer as the Ag-base bonding metal layer is particularly successful in enhancing the effect of reducing the contact resistance. Ratio of formation area of the Ag-base bonding metal layer on the light emitting layer section side to the Ag-base layer is preferably adjusted within a range from 1% to 25%, similarly to that of the above-described Au-base bonding metal layer.

Next, in the light emitting device of the invention, the Au-base layer may have a coupled layer. This sort of light emitting device can be fabricated by a method comprising disposing a first Au-base layer, having Au as a major component and destined for one part of the coupled layer, on the bonding-side main surface of the compound semiconductor layer, which is a main surface thereof opposite to the main surface destined for the light extraction surface, disposing a second Au-base layer, having Au as a major component and destined for another part of the coupled layer, on the bonding-side main surface of the device-substrate, which is a main surface thereof destined to be disposed on the light emitting layer section side, and bonding the first Au-base layer and the second Au-base layer in close contact with each other.

When the device-substrate and the compound semiconductor layer is bonded, it is allowable to stack them while placing the Au-base layers in between, and to subject the stack of this state to bond annealing.

According to these fabrication methods of the invention, the individual first and second Au-base layers are formed dividedly on the compound semiconductor layer side and on the device-substrate side, and bonded in close contact with each other. The fellow Au-base layers can readily be fused at relatively low temperatures, so that a sufficient bonding strength can be obtained even under a low annealing temperature for bonding.

It is allowable herein to adopt, as specific methods for forming the metal layer, vapor phase film formation processes such as vacuum evaporation and sputtering, and also to adopt electro-chemical film formation processes such as electroless plating and electroplating.

### BRIEF DESCRIPTION OF THE DRAWINGS

FIG. 1 is a schematic drawing showing, in a form of stacked structure, a first embodiment of a light emitting device to be applied with the invention.

FIG. 2 is an explanatory drawing showing an exemplary fabrication process of the light emitting device shown in FIG. 1.

FIG. 3 is a schematic drawing showing, in a form of stacked structure, a second embodiment of a light emitting device to be applied with the invention.

FIG. 4 is an explanatory drawing showing an exemplary fabrication process of the light emitting device shown in FIG. 3.

FIG. 5 is an explanatory drawing showing another exemplary fabrication process of the light emitting device shown in FIG. 1.

FIG. 6 is a drawing showing reflectivity of various metals.

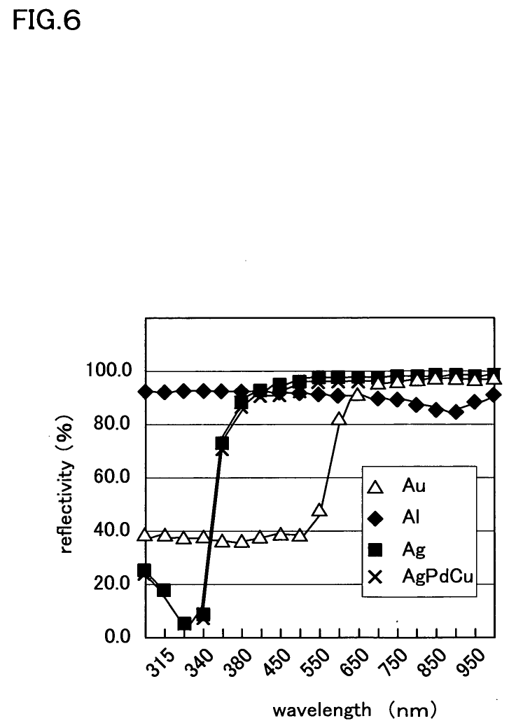

### BEST MODES FOR CARRYING OUT THE INVENTION

The following paragraphs will describe best modes for carrying out this invention, referring to the attached drawings.

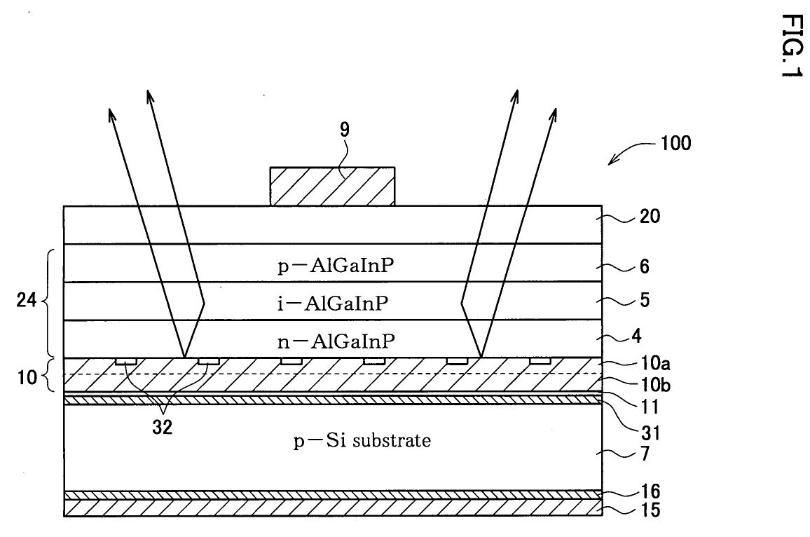

FIG. 1 is a conceptual drawing showing a light emitting device 100 as one embodiment of the invention. The light emitting device 100 is configured so that a light emitting layer section 24 is bonded, while placing a main metal layer 10 in between, to a first main surface of p-Si substrate 7 composed of a p-type Si (silicon) single crystal which is a electro-conductive substrate serves as the device-substrate.

The light emitting layer section 24 has a structure in which an active layer 5 composed of non-doped (AlₓGa₁₋ₓ)_{y}In_{1-y}P (where, 0≦x≦0.55, 0.45≦y≦0.55) is held between a first conductivity type cladding layer, which is a p-type cladding layer 6 composed of p-type (Al_{z}Ga_{1-z})_{y}In_{1-y}P (where x<z≦1) in this embodiment, and a second cladding layer having a conductivity type different from that of the first conductivity type cladding layer, which is an n-type cladding layer 4 composed of n-type (Al_{z}Ga_{1-z})_{y}In_{1-y}P (where x<z≦1) in this embodiment, and is adjustable in the emission wavelength thereof over a range from green to red regions (emission wavelength (peak emission wavelength) of 550 nm to 670 nm, both ends inclusive). In the light emitting device 100, the p-type AlGaInP cladding layer 6 is disposed on the metal electrode layer 9 side, and the n-type AlGaInP cladding layer 4 is disposed on the main metal layer 10 side. The metal electrode 9 side therefore has a positive polarity under current supply. It is to be noted that “non-doped” referred to herein means “not intentionally added with a dopant”, and never excludes possibility of any dopant components inevitably contained in the normal fabrication processes (up to 10¹³ to 10¹⁶/cm³ or around, for example).

On the main surface of the light emitting layer section 24 opposite to that facing to the substrate 7, there is formed a current spreading layer 20 composed of AlGaAs, and at the near center of the main surface thereof, there is formed a metal electrode (e.g., Au electrode) 9 through which emission drive voltage is applied to the light emitting layer section 24, so as to cover a part of the main surface. The area surrounding the metal electrode 9 in the main surface of the current spreading layer 20 serves as an extraction region of light from the light emitting layer section 24.

The p-Si substrate 7 is fabricated by slicing and polishing a Si single crystal ingot, and has a thickness of typically from 100 μm to 500 μm. It is bonded to the light emitting layer section 24 while placing the main metal layer 10 in between. The main metal layer 10 is configured as the Au-base layer as a whole.

Between the light emitting layer section 24 and the main metal layer 10, there is formed an AuGeNi bonding metal layer 32 (e.g., Ge: 15% by mass, Ni: 10% by mass) as the bonding metal layer on the light emitting layer section side, which contributes to reduction in series resistance of the device. The AuGeNi bonding metal layer 32 is formed on the main surface of the main metal layer 10 in a distributed manner, with a ratio of formation area of 1% to 25%.

Between the p-Si substrate 7 and the main metal layer 10, there is formed a first Al contact layer 31 (e.g., Al: 99.9% by mass) as the bonding metal layer on the substrate side, so as to contact with the main surface of the p-Si substrate 7. On the back surface of the p-Si substrate 7, there is formed a metal electrode (back electrode: typically an Au electrode) so as to cover the entire portion thereof. Between the metal electrode 15 and the p-Si substrate 7, there is formed a second Al contact layer 16 (e.g., Al: 99.9% by mass).

The entire surface of the first Al contact layer 31 is covered with a titanium (Ti) layer 11 as the diffusion blocking layer. Thickness of the Ti layer ranges from 1 nm to 10 μm (600 nm in this embodiment). It is also allowable to adopt, as the diffusion blocking layer, a nickel (Ni) layer in place of the Ti layer. The main metal layer 10 (Au-base layer) is arranged so as to cover the entire surface of the Ti layer 11 and so as to contact therewith. The Au-base layer in this embodiment is composed of pure Au or an Au alloy having an Au content of 95% or more.

Light from the light emitting layer section 24 is extracted in a form that the light directly emitted towards the light extraction surface side is overlaid with the light reflected on the main metal layer 10. Thickness of the main metal layer 10 is preferably as much as 80 nm or above, in view of ensuring a thorough reflective effect. The upper limit of the thickness is not specifically limited, and is appropriately determined on a balance with cost because the reflective will saturate (1 μm or around, for example).

The following paragraphs will describe a method of fabricating the light emitting device 100 shown in FIG. 1.

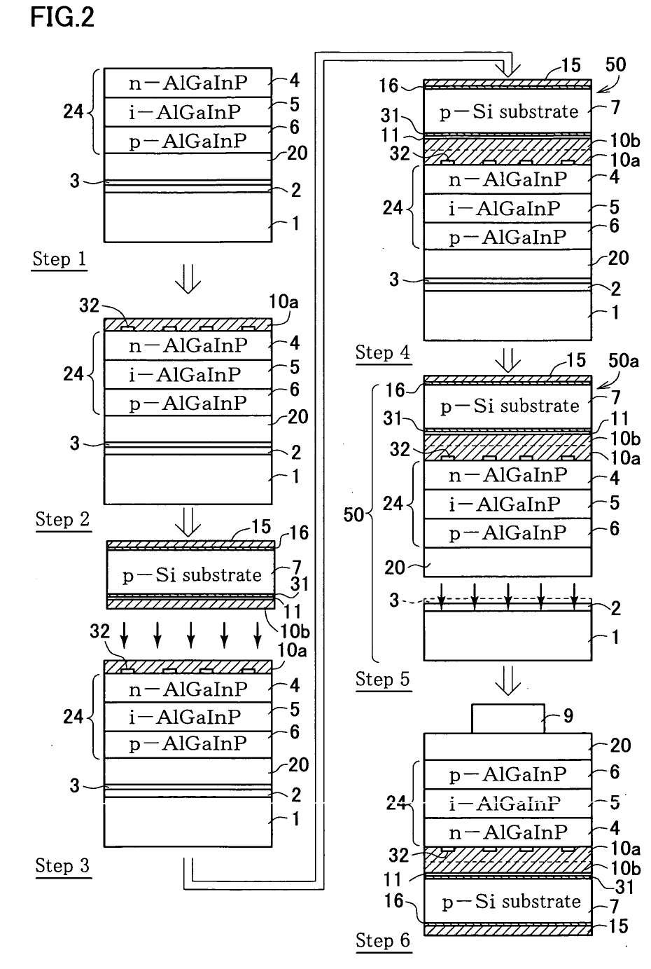

First, as shown in step 1 of FIG. 2, on the main surface of a GaAs single crystal substrate 1 which is a semiconductor single crystal substrate serving as a substrate for growing thereon the light emitting layer, a p-type GaAs buffer layer 2 of typically 0.5 μm thick, AlAs separation layer 3 of typically 0.5 μm thick and the current spreading layer 20 of typically 5 μm thick, composed of a p-type AlGaAs are epitaxially grown in this order. Thereafter, the p-type AlGaInP cladding layer 6 of 1 μm thick, the AlGaInP active layer (non-doped) 5 of 0.6 μm thick, and the n-type AlGaInP cladding layer 4 of 1 μm thick are epitaxially grown in this order.

Next, as shown in step 2, the AuGeNi bonding metal layer 32 is formed in a distributed manner on the main surface of the light emitting layer section 24. After the formation of the AuGeNi bonding metal layer, annealing for alloying is carried out in a temperature range from 350° C. to 500° C. Thereafter, a first Au-base layer 10a is formed so as to cover the AuGeNi bonding metal layer 32. The annealing for alloying results in formation of an alloyed layer between the light emitting layer section 24 and the AuGeNi bonding metal layer 32, and in a sharp reduction in the series resistance. On the other hand, as shown in step 3, on both main surfaces of a separately-obtained p-Si substrate 7 (boron-doped, resistivity of approximately 8 Ω·cm), the first and the second Al contact layers 31, 16, which will later be the bonding metal layers on the substrate side, are formed, and then subjected to annealing for alloying in a temperature range from 300° C. to 650° C. The Ti layer 11 (thickness: 600 nm, for example) and the second Au-base layer 10b are formed in this order on the first Al contact layer 31. On the other hand, a back electrode layer 15 (typically composed of an Au-base metal) is formed on the second Al contact layer 16. In these steps, the individual metal layers can be formed typically by sputtering or vacuum evaporation.

Next, as shown in step 4, the second Au-base layer 10b on the p-Si substrate 7 side is stacked on the first Au-base layer 10a formed on the light emitting layer section 24, pressed to each other, and the stack is subjected to bond annealing at 180° C. to 360° C., typically at 200° C., to thereby form a bonded substrate 50. The p-Si substrate 7 is bonded to the light emitting layer section 24 while placing the first Au-base layer 10a and the second Au-base layer 10b in between. The first Au-base layer 10a and the second Au-base layer 10b are fused by the bond annealing, to thereby produce the main metal layer 10. Because both of the first Au-base layer 10a and the second Au-base layer 10b are mainly composed of Au less likely to be oxidized, the bond annealing can be carried out even in the air without problems.

In addition, the Ti layer 11 which functions as the diffusion blocking layer is inserted between the second Au-base layer 10b and the first Al contact layer 31. This successfully blocks diffusion of the Al component from the first Al contact layer 31 towards the second Au-base layer 10b during formation of the second Au-base layer 10b, and thereby effectively suppresses leakage of the Al component to the second Au-base layer 10b, and further to the first Au-base layer 10a fused therewith. This consequently prevents a nonconformity such as purple coloration of the reflective surface of the finally-obtained main metal layer 10 due to the Al component, and can realize a desirable reflectivity. It is also advantageous that the main metal layer 10 can keep the bonding strength between the p-Si substrate 7 and the light emitting layer section (compound semiconductor layer) 24.

Next the process advances to step 5, wherein the bonded substrate 50 is dipped in an etching solution typically composed of a 10% aqueous hydrofluoric acid solution, and an AlAs separation layer 3 formed between the buffer layer 2 and the light emitting layer section 24 is selectively etched, to thereby remove the GaAs single crystal substrate 1 (opaque to the light from the light emitting layer section 24) from a stack 50a comprising the light emitting layer section 24 and the p-Si substrate 7 bonded thereto. It is also allowable herein to adopt a process in which an etch stop layer composed of AlInP is preliminarily formed in place of the AlAs separation layer 3, the GaAs single crystal substrate 1 is then removed together with the GaAs buffer layer 2 using a first etching solution having a selectivity to GaAs (e.g., ammonia/hydrogen peroxide mixed solution), and the etch stop layer is then etched off using a second etching solution having a selectivity to AlInP (e.g., hydrochloric acid: hydrofluoric acid may be added for removing Al oxide layer).

Next, as shown in step 6, the electrode 9 for wire bonding (bonding pad: FIG. 1) is formed so as to cover a part of the main surface of the current spreading layer 20 exposed after the removal of the GaAs single crystal substrate 1. This is followed by general methods of dicing to produce semiconductor chips, fixing each chip to a support, subjecting the chip to wire bonding with lead wires and molding the chip with a resin.

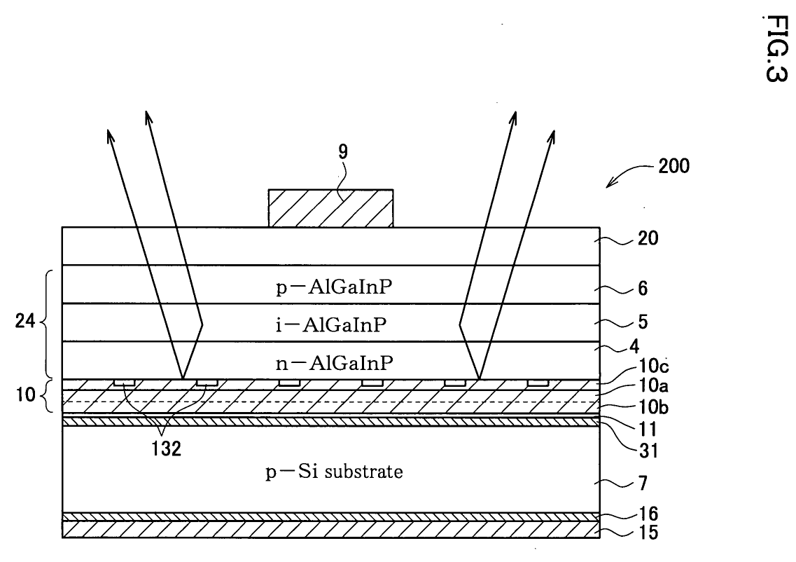

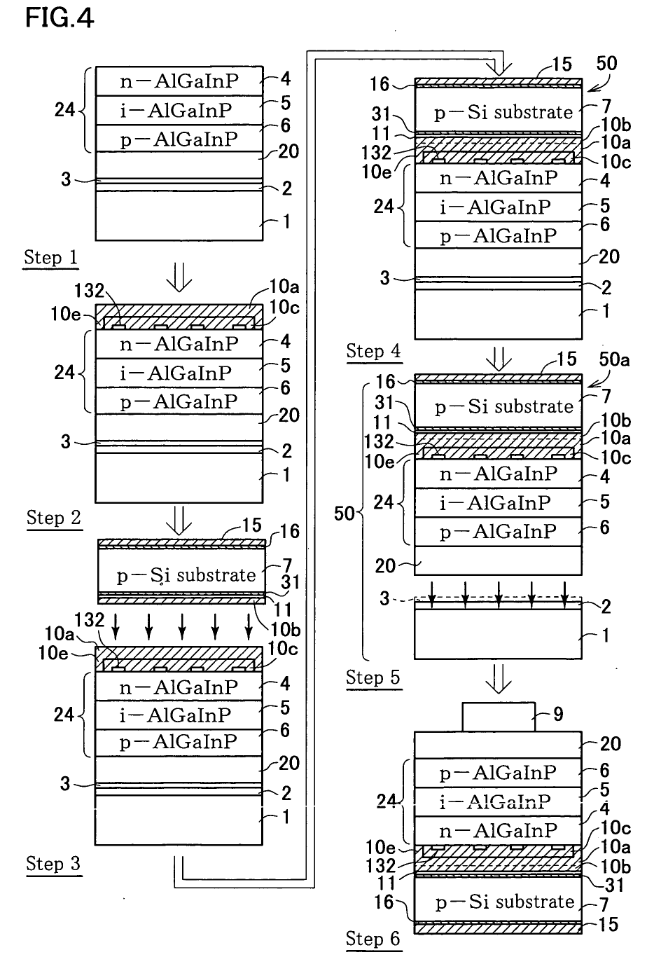

Although the reflective surface in the above-described embodiment was formed by the first Au-base layer 10a, it is also allowable, as shown in a light emitting device 200 in FIG. 3, to provide the Ag-base layer 10c as being inserted between the first Au-base layer 10a and the light emitting layer section 24. In this case, an Ag-base bonding metal layer 132 composed of AgGeNi (e.g., Ge: 15% by mass, Ni: 10% by mass) is formed as the bonding metal layer on the light emitting layer section side, in a distributed manner in place of the Au-base bonding metal layer. The other portions are same with those in the light emitting device shown in FIG. 1. FIG. 4 shows an exemplary fabrication process of the device. Differences from the fabrication process shown in FIG. 2 reside in that an Ag-base boning metal layer 132 is formed in a distributed manner in place of the Au-base bonding metal layer 32 in step 2, the bond annealing is carried out in a temperature range from 350° C. to 660° C., and the Ag-base layer 10c and the first Au-base layer 10a are formed in this order. Other processes are basically same with those shown in FIG. 2.

It is preferable herein to adopt the following method, if removal of the substrate for growth of the light emitting layer by etching may result in corrosion of the Ag-base layer 10c due to the etching solution used therefor. That is, as shown in step 3, the first Au-base layer 10a in contact with the Ag-base layer 10c is formed with a larger area than the Ag-base layer 10c, so that the outer circumference of the Ag-base layer 10c falls inside the outer circumference of the first Au-base layer 10a. This makes the Ag-base layer 10c wrapped by the first Au-base layer 10a, and the outer circumferential surface of the Ag-base layer 10c is protected by the outer circumferential portion 10e of the first Au-base layer 10a having a high corrosion resistance, so that the Ag-base layer 10c becomes less susceptible to etching of the substrate (GaAs single crystal substrate 1) for growth of the light emitting layer carried out in step 5. When the GaAs single crystal substrate 1 is used as the light emitting layer growth substrate, and is dissolved and removed using an ammonia/hydrogen peroxide mixed solution as an etching solution, which is strongly corrosive to Ag, adoption of the above-described structure makes it possible to dissolve and remove the GaAs single crystal substrate 1 without problems.

The individual layers of the light emitting layer section 24 can be formed also by using an AlGaInN alloy. As the light emitting layer growth substrate allowing the light emitting layer section 24 to grow thereon, a sapphire substrate (insulator) or a SiC single crystal substrate can typically be used, in place of the GaAs single crystal substrate. Although the individual layers of the light emitting layer section 24 in the above-described embodiment were stacked in the order of the n-type cladding layer 4, the active layer 5 and the p-type cladding layer 6 as viewed from the substrate side, the order may be inverted so as to form the p-type cladding layer, active layer, and n-type cladding layer in this order as viewed from the substrate side.

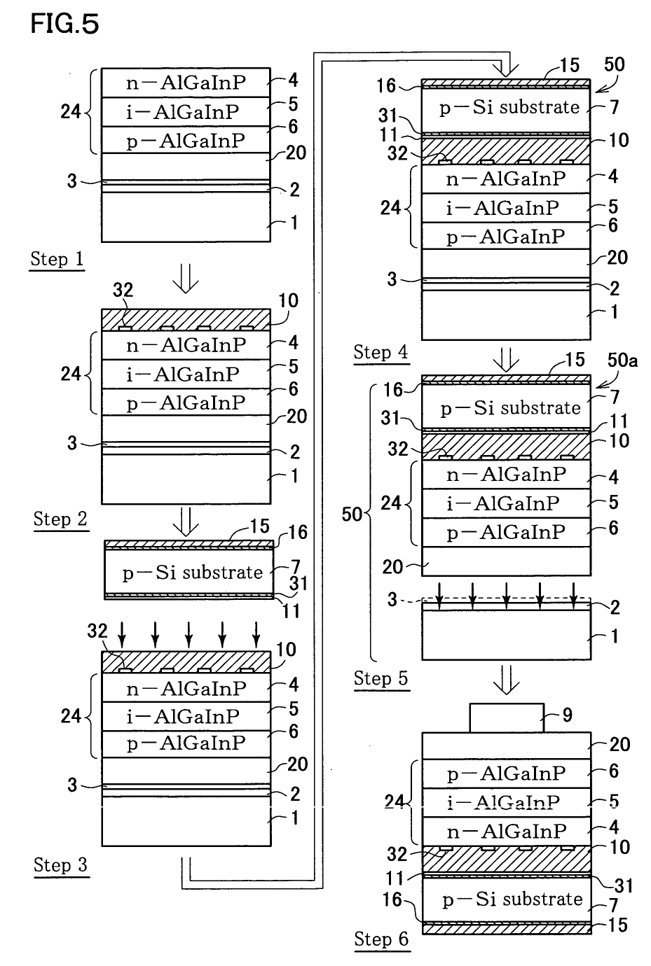

It is still also allowable, as shown in FIG. 5 (step 3), to form the main metal layer 10 only on either of the p-Si substrate 7 (device-substrate) and the light emitting layer section 24 (compound semiconductor layer), and to bond them. In this case, it is necessary to set temperature of the bond annealing (step 4) to 200° C. to 700° C., which is a little higher than in the case shown in FIG. 2, but the provision of the Ti layer (or Ni layer) 11 as the diffusion blocking layer can thoroughly suppress the diffusion of Al into the main metal layer 10, and thereby the bonding is accomplished without problems.

1. A light emitting device using a first main surface of a compound semiconductor layer portion, having a light emitting layer section therein, as a light extraction surface, and having, on the second main surface side of the compound semiconductor layer, a device-substrate bonded thereto while placing, in between, a main metal layer having a reflective surface reflecting light from the light emitting layer section towards the light extraction surface side,
the device-substrate being composed of a Si substrate having a conductivity type of p type, and
the device-substrate having, as being formed directly on the main surface thereof on the main metal layer side, a contact layer having Al as a major component.

2. The light emitting device as claimed in claim 1, wherein the light emitting layer section has, as being disposed therein, a p-type compound semiconductor layer on the light extraction surface side thereof, and an n-type compound semiconductor layer on the main metal layer side thereof, and
the n-type compound semiconductor layer being bonded to the p-type Si substrate while placing the main metal layer in between.

3. The light emitting device as claimed in claim 2, wherein the light emitting layer section is configured by a double heterostructure which comprises a p-type cladding layer as the p-type compound semiconductor layer, an n-type cladding layer as the n-type compound semiconductor layer, and an active layer formed between the p-type cladding layer and the n-type cladding layer.

4. The light emitting device as claimed in claim 1, further comprising, as being inserted between the contact layer and the main metal layer, a diffusion blocking layer composed of a electro-conductive material, capable of blocking diffusion of an Al component contained in the contact layer.

5. The light emitting device as claimed in claim 4, wherein a portion of the main metal layer including at least the boundary with the diffusion blocking layer is composed of an Au-base layer having Au as a major component, and
the diffusion blocking layer is composed of a diffusion blocking metal layer having either one of Ti and Ni as a major component.

6. The light emitting device as claimed in claim 5, wherein the Au-base layer forms the reflective surface.

7. The light emitting device as claimed in claim 5, wherein an Ag-base layer having Ag as a major component, inserted between the Au-base layer and the compound semiconductor layer, forms the reflective surface.

8. The light emitting device as claimed in any one claim 5, wherein the Au-base layer has a coupled layer.

9. A method of fabricating the light emitting device described in claim 8, comprising:
disposing a first Au-base layer, having Au as a major component and destined for one part of the coupled layer, on the bonding-side main surface of the compound semiconductor layer, which is a main surface thereof opposite to the main surface destined for the light extraction surface,
disposing a second Au-base layer, having Au as a major component and destined for another part of the coupled layer, on the bonding-side main surface of the device-substrate, which is a main surface thereof destined to be disposed on the light emitting layer section side, and
bonding the first Au-base layer and the second Au-base layer in close contact with each other.

10. The method of fabricating the light emitting device as claimed in claim 9, wherein the device-substrate and the compound semiconductor layer are bonded by stacking them while placing the Au-base layers in between, and by subjecting the stack of this state to bond annealing.
